(19) United States
(12) Patent Application Publication
(10) Pub. No.: US 2008/0094644 A1
(43) Pub. Date: Apr. 24, 2008

(54) Method And Device For Converting Source Image Data Into Target Image Data

(76) Inventor: Andreas Paul, Vaterstetten (DE)

Correspondence Address: SCHIFF HARDIN, LLP;PATENT DEPARTMENT, 6600 SEARS TOWER, CHICAGO, IL, 60606-6473, US

(21) Appl. No.: 11/574,681

(22) PCT Filed: Sep. 8, 2005
(86) PCT No.: PCT/EP05/09678

§ 371 Date: Mar. 5, 2007

(30) Foreign Application Priority Data
Sep. 15, 2004 (DE) 10 2004 044 647.4

(51) Int. Cl. G03F 3/08; G06F 3/12

(52) U.S. Cl. 358/1.1; 358/520

(57) ABSTRACT

In a method or device for conversion of source image data into target image data, source image data are processed to generate a source image in at least one first color. The target image data is generated for generation of a target image in at least one second color differing from the first color. With the source of image data for each image element of the target image, the brightness value of an inking of the source image in a region of the image element is determined. Dependent on the determined brightness values, the target image data are generated via which each image element in the target image generated in the second color has a substantially same brightness value as the brightness value determined for the respective image element in a source image.

### BACKGROUND

The preferred embodiment concerns a method and a device for conversion of source image data into target image data in which source image data are processed for generation of a source print image in at least one first color. Target image data for generation of a target print image are generated in at least one second color differing from the first color.

For optimal representation of images to be output with the aid of an output apparatus, these images are optimized for the output with the aid of a special output apparatus. Optimized image data are thereby generated that are supplied to the output apparatus. The optimization of the image data in particular concerns the possible color representation and the effect of factors influencing the output image. Such factors are in particular when printers are used as output apparatuses, the area coverages of the individual toner colors being used for generation of the print image and the tonal value curves. The area coverages and tonal value curves of all print colors used by the printer are advantageously taken into account. These print colors are also designated as primary colors and are cyan, magenta, yellow, and black in known printers. Print images generated with the aid of these primary colors are also designated as CMYK images, whereby C designates the color cyan, M designates the color magenta, Y designates the color yellow and K designates the color black. As an alternative to or in addition to the colors CMYK, specially mixed special colors can be used for generation of print images or for generation of mixed images.

Should an image optimized for a specific output apparatus be rendered or output with the aid of a different output apparatus, the representation of the output image is often inadequate. In particular the representations of full-color photographs given the output with the aid of black-and-white printers are in part no longer recognizable. However, it is desirable that the representation of the output color optimally approaches the representation in full-color in the effect on the observer. The individual colors and shadings should also be well differentiable from one another for the observer. In particular given a reduction of the colors used in the output of the image, a differentiability is in fact no longer possible to the degree as is possible given the presentation of the original image in full color and/or a special color; however, the individual image components should be differentiable for the observer in the same manner as in an original image.

Given other output apparatuses such as, for example, monitors or projectors, red, green, blue (RGB) are used as primary colors. For example, it is conceivable to convert a CMYK full color image for output with the aid of a black-and-white printer into an RGB image or to directly use existing RGB image specifications and then to convert into a black-and-white image. However, the problem thereby arises that the RGB color space is visually not equally spaced, such that no optimal gradation of the color or brightness differences of the output image can be generated. Also, not all colors can be reproduced with the aid of the RGB color space. In particular the primary printing colors yellow and cyan of a full color printer belong to these colors. Many special colors can likewise not be described with the aid of the RGB color space. Different printing conditions such as, for example, the paper types and the layer thickness are also not taken into account in this conceivable method. Given an attempt of the direct conversion of CMYK images into black-and-white images, special colors can also not be taken into account since no color association is known for these special colors or this color association can only be determined via complicated measurements. In offset printing methods images with these special colors are generated given use of an additional printing plate that is exposed corresponding to the color proportions of the special color at the overall image. For generation of a print image on a carrier material, this print plate is then wetted with a corresponding print color and subsequently transfer-printed onto the carrier material. Given electrographic printers a toner image in this special color is generated that is printed over further toner images, at least given multicolor printing.

A method and an apparatus for automatic color conversion of a source color into a destination color are known from the document DE 694 21 018 T2, which method and apparatus convert all regions corresponding to the source color in a document to be reproduced into the destination color. A method for printing process transformation of the color printing for black-and-white images is known from the document DE 102 05 476 A1, in which method apparatus-dependent color values are taken into account in the transformation. A conversion of RGB color values for display of an image on a monitor into C-M-Y-K color values for output of a color image on a printer is known from the document GB 2 213 674 A.

### SUMMARY

It is an object to specify a method and a device for conversion of source image data into target image data, in which method and device target data image data for generation of a target image in at least one second color differing from the first color are generated in a simple manner from source image data for generation of a source image in at least one first color, via which a high-quality presentation of the target image is possible.

In a method or device for conversion of source image data into target image data, source image data are processed to generate a source image in at least one first color. The target image data is generated for generation of a target image in at least one second color differing from the first color. With the source of image data for each image element of the target image, the brightness value of an inking of the source image in a region of the image element is determined. Dependent on the determined brightness values, the target image data are generated via which each image element in the target image generated in the second color has a substantially same brightness value as the brightness value determined for the respective image element in a source image.

### BRIEF DESCRIPTION OF THE DRAWINGS

FIG. 1 is a general block diagram for generation of a target print image according to the preferred embodiment;

FIG. 2 is a workflow plan for conversion of source image data into target image data under consideration of properties of a desired printer and REAL printer according to a first embodiment of the preferred embodiment; and

FIG. 3 is a workflow plan for generation of target image data from source image data according to a second embodiment of the invention.

### DESCRIPTION OF THE PREFERRED EMBODIMENTS

For the purposes of promoting an understanding of the principles of the invention, reference will now be made to the preferred embodiments illustrated in the drawings and specific language will be used to describe the same. It will nevertheless be understood that no limitation of the scope of the invention is thereby intended, and such alterations and further modifications in the illustrated device and such further applications of the principles of the invention as illustrated as would normally occur to one skilled in the art to which the invention relates are included.

Via the method of the preferred embodiment it is achieved that the target image has the same brightness distribution as the source image, whereby a similar optical impression arises in the observer. In particular individual regions of the target image can be differentiated from one another in the same manner as these images are in the source image.

A second aspect of the preferred embodiment concerns a device for conversion of source image data into target image data. The source image data for generation of a print image in at least one first color are processed with the aid of a data processing unit. The data processing unit generates target image data for generation of a print image in at least one second color differing from the first color. With the aid of the source image data, the data processing unit also determines a brightness value of the inking of the source image in the region of the image point for each image point of a target image. Dependent on the determined brightness value, the data processing unit also generates target image data via which each image point in a print image generated in the second color has the same brightness value as the brightness value determined for the respective image point in the source image.

Target image data can be generated from the source image data with the aid of such a device, via which target image data a target image can be output that generates contour, contrast and brightness impressions in the observer similar to a source image generated with the aid of the source image data.

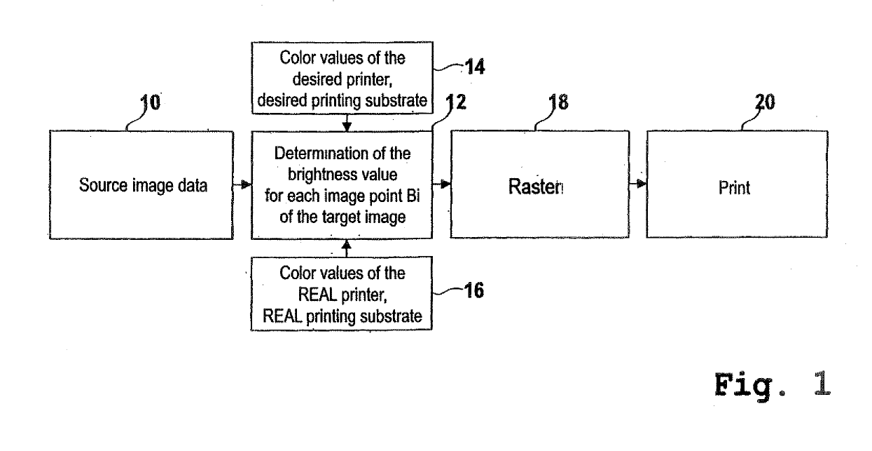

A general block diagram that shows the processing according to the preferred embodiment of source image data for generation of a print image with the aid of a printer is shown in FIG. 1. Source image data 10 have already been optimized for generation of a print image on a desired printing substrate with the aid of a desired printer. The desired printing substrate is a concrete carrier material to be used on which a print image should be generated. However, the color values of the desired printer and the reproduction properties of the printing substrate 14 are also taken into account in the processing of the source image data for generation of the target image data. The color values of the REAL printer and the properties of the REAL printing substrate 16 that are taken into account in the generation of the target image data are also known.

The REAL printer is a printer on which a target image should be output, the optical impression of which target image is at least approximate to a print image output by a desired printer with the aid of the source image data. With the aid of a processing routine 12, a brightness value is determined with the aid of the source image data 10 (dependent on the known color values of the desired printer and the properties of the desired printing substrate 14) for each image point of the target image to be generated. Dependent on the determined brightness value, target image data are generated under consideration of the color values of the REAL printer and the properties of the REAL printing substrate 16. Target image data generated in a processing process 12 are rastered in a raster process 18 under consideration of the output properties of the REAL printer and a print data stream is generated. This print data stream is supplied to a printer (not shown) that generates a print image on the REAL printing substrate in a printing process 20.

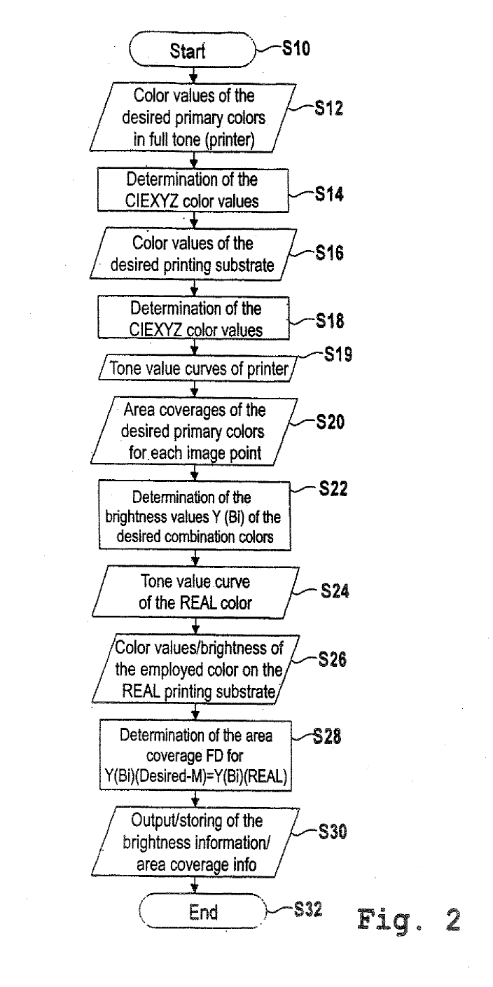

A workflow plan for conversion of source image data into target image data according to a first embodiment of the invention is shown in FIG. 2. The workflow is started in step S10. In step S12 the printer-dependent color values of the desired primary colors of the desired printer are subsequently determined in full tone. These color values are, for example, stored in a memory range from which they are read out in step S12. Starting from the color values of the desired printing substrate determined in step S16, the CIEXYZ color values of the desired printing substrate are determined in step S18. The tone value curves of the desired primary colors are then determined in the source image in step S19. In step S20 the degrees of area coverage of the primary colors at each image point are then determined from the image data.

For each image point of the source image and/or for each region of the source image associated with a target image point, a brightness value of the desired combination colors is determined dependent on the determined CIEXYZ color values of the desired primary colors of the printer in full tone, on the determined CIEXYZ color values of the desired printing substrate and on the area coverages and tone value curves of the desired primary colors in the source image. The tone value curve of the REAL color is also then determined in a step S24 and the color values and the brightness of the employed colors on the REAL printing substrate are determined in a step S26.

Starting from the brightness value determined in step S22, in step S28 the area coverage of the desired print image is determined dependent on the tone value curve of the REAL color (determined in step S24) as well as the color values and the brightness of the employed color on the REAL printing substrate (determined in step S26). The brightness of the desired combination color at the source image point thereby corresponds to the brightness of the employed color at the target image point. Target image data that are stored in a step S30 are generated with the aid of the brightness information and area coverage information. Alternatively, the target image data can be transferred directly to a printer.

The order of the steps specified in the workflow plan according to FIG. 2 is not obligatory for implementation of the workflow of the preferred embodiment. In particular the steps S12 through S20, S24 and S26 can be executed in a different order, for example successively at the start of the workflow.

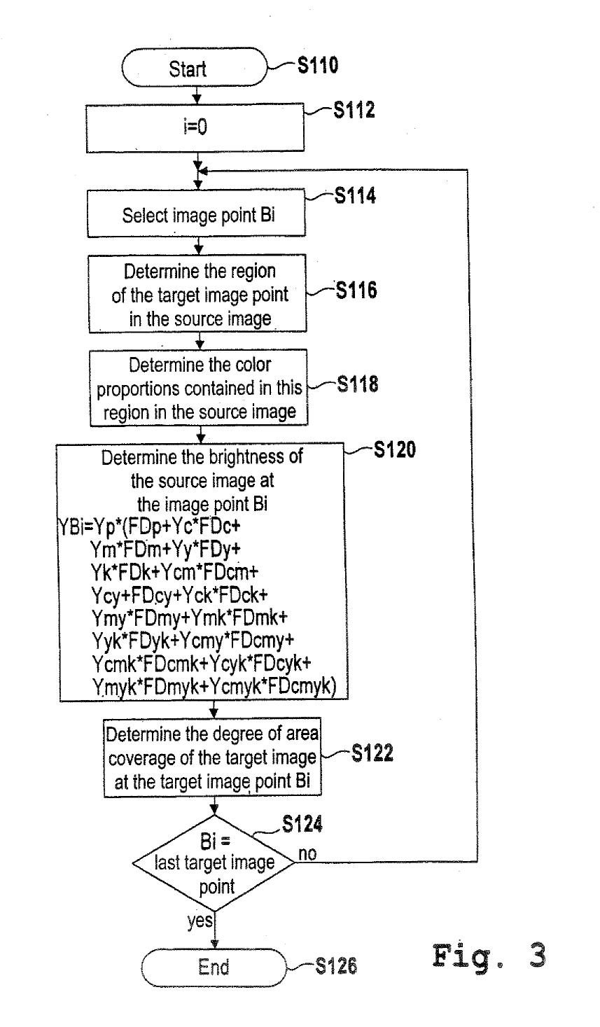

A workflow plan for conversion of source image data into target image data with the aid of the method according to a second embodiment is shown in FIG. 3. The workflow is started in a step S110. The value 0 is subsequently assigned to the variable i in a step S112. The image point with the variable i is subsequently selected in a step S114. In the first pass the first image point of the target image to be generated is selected, meaning the image point B0. A region corresponding to the target image point Bi in the source image is then determined in a step S116.

Which colors are contained in the region determined in step S116 and which color proportion each of these colors has is then determined in a step S118. The color proportion is advantageously the area of the respective primary color or of the respective combination color that is visible given an observation of the region. The respective color proportion is advantageously determined as a percentile color proportion. The brightness of the source image in the region of the target image point Bi is subsequently determined in a step S120. Via incorporation of a variable Yp and the area coverage value FDp, the reflection properties of the paper and the degree of area coverage of the paper (i.e. the non-printed area in the region of the target image point Bi) are taken into account in the determination of the brightness Y for this target image point Bi. Corresponding to its area coverage proportions, each primary color present in the printer and each combination color possible with the aid of these primary colors and, if applicable a special color is also taken into account in the determination of the brightness Y for the image point Bi. In a step S122 the degree of area coverage FD of the target image at the image point Bi is subsequently determined in order to generate the same brightness Y at the target image point Bi as in the corresponding region in the source image. The determined degree of area coverage FD is used as a target image parameter for generation of the target image and is stored. In a step S124 it is subsequently checked whether the image point Bi is the last image point of the target image. If this is the case the workflow is ended in a step S126. If it is determined in step S124 that the image point Bi is not the last image point, the workflow is continued in step S114 and repeated until the brightness value Y and the degree of area coverage FD has been determined for each target image point Bi of the target image.

With the aid of the workflow of the preferred embodiment shown in FIG. 3, the color and brightness differences present in the source image can then also be well differentiated given a consideration of the target image when the source image comprises a plurality of colors and the target image is reproduced in only one color. Given the one-color reproduction of a multi-colored source image, the brightnesses can thus be graded as given the optimal output of the source image such that a comparison capability of the color differences is also well possible given the one-color output of the image.

As an alternative to the workflow shown in FIG. 3, the determination of the brightness can occur not per image point but rather per object. In particular the brightness of a letter specified with the aid of a font and a graphic object determined with the aid of a vector can thus be determined. The brightness of the source image can thus also be determined for individual objects contained in this source image in order to be able to then represent these objects with the same brightness in the target image. Combinations of the described possibilities for determination of the brightness of regions of the source image are also possible.

If the concrete properties of the primary colors of a printer (the tone value curves of the printer) are not known and/or the brightness of the printing substrate (i.e. of the carrier material) is not known, typical standard values or norm values (for example from Standard ISO 13637) can also be used to determine the brightness of objects or regions in the source image and to determine the degrees of area coverage in the target image. In particular no normalized brightness values for combination colors are contained in the current standards. In order to determine the brightness value of a combination color made from cyan and magenta, either a measurement of the brightness must be conducted or an existing reference value must be used.

The CIELAB color space according to ISO 2846 is generally used as a general measure for the color differences in the reproduction of images, in particular in the output of print images with the aid of a printer. ISO 2846 establishes a series of properties for print colors conforming to standards. Given the reproduction of an image with the aid of a printer, the properties of the carrier material and the color reproduction properties of the printer or copier are in particular decisive for the optical effect of the print image on the observer.

If the same effect should be generated given the one-color reproduction of the print image as given the output of the same print image on a multicolor printer or given the output of the same print image in a different print color, the influences of the carrier material on the optical effect of the print image as well as the tone value curves of the desired printer and of the REAL printer must also be taken into account. It is thus in particular required to take into account the properties of the carrier material in the determination of the brightness value when coated papers, LWC papers, uncoated papers or uncoated yellowish papers are used as carrier material. The specific color of the carrier material is also to be taken into account given the use of carrier material that does not have the color white.

The advantage of the use of the CIELAB color space is that this color space is visually equally spaced. Alternatively, other color space spaces that are equally visually spaced can also be used as a basis for the preferred embodiment. Given equally-spaced color spaces an interval measure ΔE* can be determined between two colors or between a combination color and a primary color. This interval measure serves as a measure for the perceived differences between desired color and REAL color. These perceived differences can thereby be quantified. All possible colors (even special colors) can also be classified in the CIELAB color space. The properties of the special color can be determined relatively simply via special measurements for determination of the CIELAB properties of this special color.

In contrast to the CIELAB color space, the use of the unequally-spaced RGB color space is not as advantageous since no matching toner value can be determined in the RGB color space for special colors for which no color association is known. Since the RGB color space is not visually equally spaced, the brightness of a region in the source image can also only be determined with difficulty, whereby the determination of the required area coverage in the target print color is very complicated.

A plurality of colors in the RGB color space can also not be defined and specified since they lie outside of the definition range of the RGB color space. Primarily special colors and the full tone yellow and cyan of four color raster printing belong to these colors that cannot be specified.

In contrast to this, all theoretically combinable and generatable colors are defined in the CIELAB color space. Differences in the reproduction of a print image can also be taken into account in the preferred embodiment, for example, due to different print conditions, in particular the dependency on the employed paper types, the layer thickness of the individual colors and the tone value curves of a specific output apparatus. A calculation of the grey value proportions of arbitrary combination colors (including special colors) is simply possible with the aid of the method of the preferred embodiment. The calculation of the grey value proportions can occur under consideration of the properties of a desired printing system for which the print image is originally optimized.

The properties of the printing system or the properties of a class of printing systems can also be taken into account in the generation of target image data so that the color differences in the target print image are comparable with those in the source print image. The source print data for the output of a source print image are generally optimized for a source image printer, whereby the source image data for the output of the source print image can be specially adapted with the aid of the source image printer. Target image data for output of a target image on a target image printer are generated from the source image data with the aid of the method of the preferred embodiment, whereby source image and target image can also have different resolutions.

However, the method of the preferred embodiment can also be advantageously employed when the source image printer differs from the target image printer only in the print color used. The source image printer can thus use a first print color and the target image printer can use a second print color differing from the first print color. The optical effect of these print colors naturally differ. The method then serves such a target print image is generated that is comparable in the optical impression for the observer. The method can also be advantageously used when the source image printer in particular has three primary colors (cyan, magenta, yellow) required for full color printing as welt as black and/or a special color.

Starting from the degrees of area coverage of the individual colors used in the source image printer and the brightness values of the individual full tones, the brightness of the combination color can be determined under consideration of the tone value increase. The tone value for the same region in the target image can be determined (dependent on the target image color) with the aid of the determined brightness value. The reflection factor of a region printed with the aid of four color printing can be calculated according to the following formula:

R_{R}=R_{P}*(FD_{P}+R_{C}*FD_{C}+RM*FD_{M}+R_{Y}*FD_{Y}+RK*FD_{K}+CR_{M}*FD_{CM}+R_{CY}+FD_{CY}+R_{CK}*FD_{CK}+R_{MY}*FD_{MY}+R_{MK}*FD_{MK}+R_{YK}*FD_{YK}+R_{CMY}*FD_{CMY}+R_{CMK}*FD_{CMK}+R_{CYK}*FD_{CYK}+R_{MYK}*FD_{MYK}+R_{CMYK}*FD_{CMYK}),

whereby:

R_{P} is the reflection factor of the carrier material (advantageously of the paper),

R_{C} through R_{CMYK} are the reflection factors of respective layers specified in the index and possibly printed atop one another,

FD_{P} is the degree of area coverage of the paper, and

FD_{C} through FC_{CMYK} are the degrees of area coverage of the respective layers specified in the index and possibly printed atop one another.

The reflection factors R of the color layers printed atop one another can be calculated at least approximately via multiplication of the reflection factors of the individual layers. Alternatively, the reflection factors of the colors printed atop one another can also be measured or be derived from tables/standards. In order to obtain independent values from the reflection properties of the paper, the reflection factors of the full tones on the paper are calculated via division by the reflection factor of the unprinted paper. It is thereby avoided that the reflection properties of the carrier material are taken into account multiple times given superimposed printing in multiple full tones. The full tones are the primary colors CMYK (which stands for cyan, magenta, yellow and black) of the printer.

The determination of the reflection factor of a combination color made up of cyan and magenta on a carrier material with the reflection factor R_{P} is calculated according to the following formula:

R_{CM}=(R_{C}/R_{P})·(R_{M}/R_{P}).

The degrees of area coverage FD specify the probabilities with which the corresponding primary color or combination color is present at a specific point. The probability to not come across this color or this combination color at a specific location or in a specific region can thus be specified by 1−FD. The degree of area coverage FD for any arbitrary combination color can be determined via multiplication of the probabilities for individual primary colors contained in combination colors. For example, the probability of the degree of area coverage for a combination color made up of cyan and magenta is calculated as follows:

FD_{combination}=FD_{C}·FD_{M}·(1−FD_{Y})·(1−FD_{K}).

In the determination of the degrees of area coverage a nominally controlled degree of area coverage or toner value is advantageously not to be assumed; rather, the actual degree of area coverage of the respective color that is generated on the paper is to be assumed.

This actual degree of area coverage generated on the carrier material is determined via addition of the tone value increase relative to the nominally controlled degree of area coverage. The tone value increase curves for the textile colors (for example C, M, Y, K) are either determined and also are standardized and known for many printing methods (for example offset DIN/ISO 12647). If the reflection factors of the raster surface R_{R} for all wavelengths are known, color values and in particular also brightness values (for example Y of CIEXYZ) can be determined from these as stated, for example, in DIN 5033 (pertaining to color measurement).

The method of the preferred embodiment for conversion of color image components of a source image into optically equally effective monochrome presentations in a target image is subsequently explained for two colors (Pantone 185U and Pantone Reflect Blue U) contained in a company logo, which two colors are not printed atop one another. The company logo should be output with the aid of a black-and-white printer. The degree of area coverage of the color Pantone 185U is specified with 50% in the source image data. Given a degree of area coverage of 50%, a tone value increase of 20% is determined with the aid of the tone value curves of the source image printer or of a standard printer, such that the actual degree of area coverage of the color Pantone 185U is 70%. Given a surface printed with the color Pantone 185U, a real degree of area coverage of 70% is achieved given a desired degree of area coverage of 50%, whereby the brightness of the paper is visible on 30% of the area.

The area printed with the color Pantone Reflex Blue U is printed with a degree of area coverage of 100%. The brightness value Y of the color Pantone 185U is 25, the brightness value of the color Pantone Reflex Blue U is 9 and the brightness Y of the paper on which the source print image should be generated is 90. A brightness value for carrier material for the desired printer on which the company logo should be output in black-and-white is 86. The brightness value of the desired print color black is 2. The resulting brightness value of the area inked with Pantone 185U, which is inked at 70% with the color Pantone 185U and at 30% with the brightness of the paper, is 44.5.

If the brightness value of 44.5 should be achieved with the aid of the desired printer in black-and-white on the coated paper, the actual degree of area coverage for this area must be inked with 40% and, given a degree of area coverage of 85%, be inked black for the original area to be inked with Pantone Reflex Blue U. Starting from these actual degrees of area coverage, the degrees of area coverage for control of the desired printer are determined using the tone value curve of the desired printer, which degrees of area coverage are then adopted in the target image data. A degree of area coverage of, for instance, 30% then results for the original area to be partially inked with Pantone 185U and a degree of area coverage of, for instance, 65% results for the original area to be inked with Pantone Reflex Blue U. With the aid of these predetermined degrees of area coverage, a print image is then rastered with the aid of a raster process, via which print image the original area to be inked with Pantone 185U is inked with black toner at 40%, and the original area to be inked with Pantone Reflex Blue U is inked with black toner at 85% given a printout of the print image.

The brightness of a region in the source image can also be directly determined on the basis of the mentioned calculation methods in that Y is used instead of the reflection factor R as a measure for the brightness of the primary and combination colors. The region in the source image is, for example, the region of an image point of the target image in the source image. The brightness for a region is then calculated according to the following formula:

Y_{R}=Y_{P}*(FD_{P}+Y_{C}*FD_{C}+Y_{M}*FD_{M}+Y_{Y}*FD_{Y}+Y_{K}*FD_{K}+Y_{CM}*FD_{CM}+Y_{CY}+FD_{CY}+Y_{CK}*FD_{CK}+Y_{MY}*FD_{MY}+Y_{MK}*FD_{MK}+Y_{YK}*FD_{YK}+Y_{CMY}*FD_{CMY}+Y_{CMK}*FD_{CMK}+Y_{CYK}*FD_{CYK}+Y_{MYK}*FD_{MYK}+Y_{CMYK}*FD_{CMYK}+Y_{special}*FD_{special}),

whereby:

Y is the brightness of a primary color or of a combination color that is a respective primary color or combination color specified in an index,

Y_{P} is the brightness of the carrier material,

FD is the degrees of area coverage of the respective primary color or combination color specified in an index,

Y_{special} is the brightness of an employed special color and

FD_{special} is the degree of area coverage of the special color.

As already mentioned, the CIELAB color values in color space are known for all possible primary and combination colors. This color space is widely used, and in image processing as a Profile Connection Space (PCS). The CIELAB color values comprise a value designated with L which specifies the brightness of the color. The following relation applied between the brightness value L and the brightness Y:

$${L}^{*} = 116 \cdot \sqrt[3]{\frac{Y}{{Y}_{White}} - 16}$$

If one assumes Y_{White}=100, the Y brightness values can be directly calculated from the L* brightness values. Starting from the calculated Y brightness value of all primary colors and combination colors contained in an image point, a degree of area coverage for the target image can be determined via a comparison with the brightness value of the primary color available at the target printer, dependent on the paper properties and the tone value curves of the target image printer, via which degree of area coverage for the target image the target image effects (upon observation) contour differences and an optical impression on the observer similar to an image generated with the source image printer. The source image printer is also designated as a desired printer and the target image printer is also designated as a REAL printer.

Although preferred exemplary embodiments have been displayed and described in detail in the drawings and in the preceding specification, they should merely be viewed as purely exemplary and not as limiting the invention. It is noted that only the preferred exemplary embodiments are shown and described and all variations and modifications that presently or in the future lie within the protective scope of the invention should be protected.

1-12. (canceled)

13. A method for conversion of source image data into target image data, comprising the steps of:
processing the source image data to generate a source image in at least one first color;
generating the target image data for generation of a target image in at least one second color differing from the first color;
with aid of the source image data, for each image element of the target determining a brightness value of inking of the source image in a region of the image element; and
dependent on the determined brightness values, generating the target image data via which each image element in the target image generated in the second color has substantially a same brightness value as the brightness value determined for the respective image element in the source image.

14. A method according to claim 13 wherein the source image is a source print image or the target image is a target print image.

15. A method according to claim 13 wherein a raster image is generated in the second color with aid of the target image data, and the raster image is output with aid of a printer.

16. A method according to claim 13 wherein the reproduction properties of a first printer are taken into account in the determination of the brightness value of the inking of the source image.

17. A method according to claim 16 wherein a degree of reflection or the brightness value of a carrier material to be printed with the aid of the first printer is taken into account in the determination of the brightness value of the inking of the source image

18. A method according to claim 17 wherein the degree of reflection of the carrier material is determined with aid of a type of the carrier material, a grade of the carrier material, and a thickness of the carrier material.

19. A method according to claim 13 wherein the reproduction of the second color with aid of a printer is taken into account in the determination of the target image data.

20. A method according to claim 13 wherein a degree of area coverage in the region of the image element is taken into account in the determination of the brightness value.

21. A method according to claim 13 wherein the brightness value of the inking of the source image in the region of the image element or the generation of the target image data for said image element is implemented with aid of a CIELAB color space.

22. A method according to claim 13 wherein actual degrees of area coverage of individual color proportions of at least the first color and the second color on a carrier material are determined.

23. A method according to claim 13 wherein the image element is an image point or an image object.

24. A device for conversion of source image data into target image data, comprising:
a data processing unit that
processes the source image data to generate a source image in at least one first color,
generates the target image data for generation of a target image in at least one second color differing from the first color,
determines, with aid of the source image data, for each image element of the target image a brightness value of an inking of the source image in a region of the image element, and
generates the target image data dependent on the determined brightness via which each image element in the target image generated in the second color has substantially a same brightness value as the brightness value determined for the respective image element in the source image.

25. A device of claim 24 wherein the source image comprises a print image and the target image comprises a print image.
